(19) United States
(12) Patent Application Publication
(10) Pub. No.: US 2008/0299686 A1
(43) Pub. Date: Dec. 4, 2008

(54) METHOD FOR MANUFACTURING SEMICONDUCTOR DEVICE

(75) Inventors: Motoshige KOBAYASHI, Kanagawa-ken (JP); Masanobu Echizenya, Tokyo (JP); Shinya Takyu, Saitama-ken (JP); Noriko Shimizu, Kanagawa-ken (JP); Hideki Nozaki, Kanagawa-ken (JP); Masanobu Tsuchitani, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/871,497

(22) Filed: Oct. 12, 2007

(30) Foreign Application Priority Data
Oct. 13, 2006 (JP) 2006-280785

(51) Int. Cl. H01L 21/66

(52) U.S. Cl. 438/16; 257/E21.521

(57) ABSTRACT

A method for manufacturing a semiconductor device, includes; measuring a within-wafer distribution of a physical quantity; and etching the wafer so that the physical quantity get close to constant within the wafer. Alternatively, a method for manufacturing a semiconductor device, includes, measuring a within-wafer distribution of a physical quantity of at least one of a plurality of semiconductor layers provided in a wafer; determining a within-wafer distribution of etching amount for the at least one of the plurality of semiconductor layers based on the measured within-wafer distribution of the physical quantity; and etching the at least one of the plurality of semiconductor layers based on the determined within-wafer distribution of the etching amount so that the etching amount is locally varied within the wafer.

### CROSS-REFERENCE TO RELATED APPLICATIONS

This application is based upon and claims the benefit of priority from the prior Japanese Patent Application No. 2006-280785 filed on Oct. 13, 2006; the entire contents of which are incorporated herein by reference.

### BACKGROUND OF THE INVENTION

1. Field of the Invention

This invention relates to a method for manufacturing a semiconductor device, and more particularly to a method for manufacturing a semiconductor device where a plurality of semiconductor devices are formed from at least one wafer.

2. Background Art

When a plurality of semiconductor devices are formed from at least one wafer, it is important to reduce characteristics variations among these semiconductor devices. Many semiconductor devices have a structure where a plurality of semiconductor layers are formed on a semiconductor substrate. Such a structure is formed by processes including crystal growth, doping, etching, and polishing on the semiconductor substrate.

JP-A 2004-128079 (Kokai) discloses a technique for etching an active silicon layer of an SOI (silicon on insulator) wafer to a required thickness by using local dry etching.

### SUMMARY OF THE INVENTION

According to an aspect of the invention, there is provided a method for manufacturing a semiconductor device, including: measuring a within-wafer distribution of a physical quantity of at least one of a plurality of semiconductor layers provided in a wafer; determining a within-wafer distribution of etching amount for the at least one of the plurality of semiconductor layers based on the measured within-wafer distribution of the physical quantity; and etching the at least one of the plurality of semiconductor layers based on the determined within-wafer distribution of the etching amount so that the etching amount is locally varied within the wafer.

According to an aspect of the invention, there is provided a method for manufacturing a semiconductor device, including: measuring a within-wafer distribution of a physical quantity; and etching the wafer so that the physical quantity get close to constant within the wafer.

### BRIEF DESCRIPTION OF THE DRAWINGS

FIG. 1 is a flow chart of a method for manufacturing a semiconductor device according to the embodiment of the invention.

FIGS. 2A to 2F are conceptual views illustrating the manufacturing method of this embodiment.

FIG. 3 is a conceptual view for illustrating a process of grinding a wafer.

FIG. 4 is a graph showing the experimental result of measuring the sheet resistance distribution of a silicon wafer after grinding.

FIGS. 5A and 5B are conceptual views of local etching.

FIGS. 6A, 6B and 6C are conceptual views showing the function of local etching.

FIG. 7 is a conceptual view showing local etching by dry etching.

FIG. 8 is a conceptual view of a circuit where an plurality of semiconductor devices are connected in parallel.

FIG. 9 is a schematic view showing the cross-sectional structure of a semiconductor device manufactured by the manufacturing method according to the embodiment of the invention.

FIGS. 10A to 10F are conceptual views showing a method for manufacturing an IGBT shown in FIG. 9, the method being a first example of the embodiment of the invention. FIG. 10G is a flow chart of a part of a method for manufacturing a semiconductor device according to the embodiment of the invention.

FIGS. 11A to 11G are conceptual views showing a method for manufacturing an IGBT shown in FIG. 9, the method being a second example of the embodiment of the invention.

FIGS. 12A to 12G are conceptual views showing a method for manufacturing an IGBT shown in FIG. 9, the method being a third example of the embodiment of the invention.

FIG. 13 is a schematic view showing the cross-sectional structure of a semiconductor device manufactured by the manufacturing method according to the embodiment of the invention.

FIGS. 14A to 14E are conceptual views showing part of a method for manufacturing a MOSFET shown in FIG. 13, the method being a fourth example of the embodiment of the invention.

FIG. 15 is a cross-sectional view showing a semiconductor device that can be manufactured by the embodiment of the invention.

### DETAILED DESCRIPTION OF THE INVENTION

An embodiment of the invention will now be described with reference to the drawings.

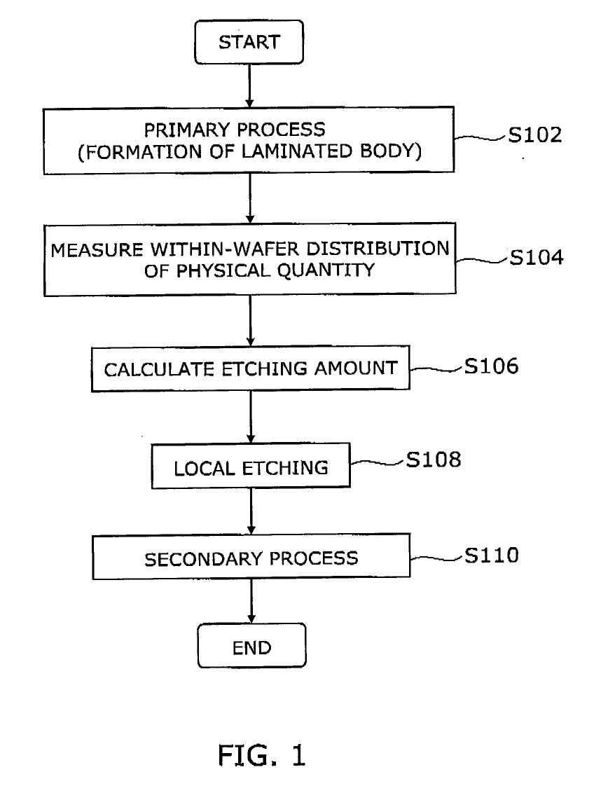

FIG. 1 is a flow chart of a method for manufacturing a semiconductor device according to the embodiment of the invention.

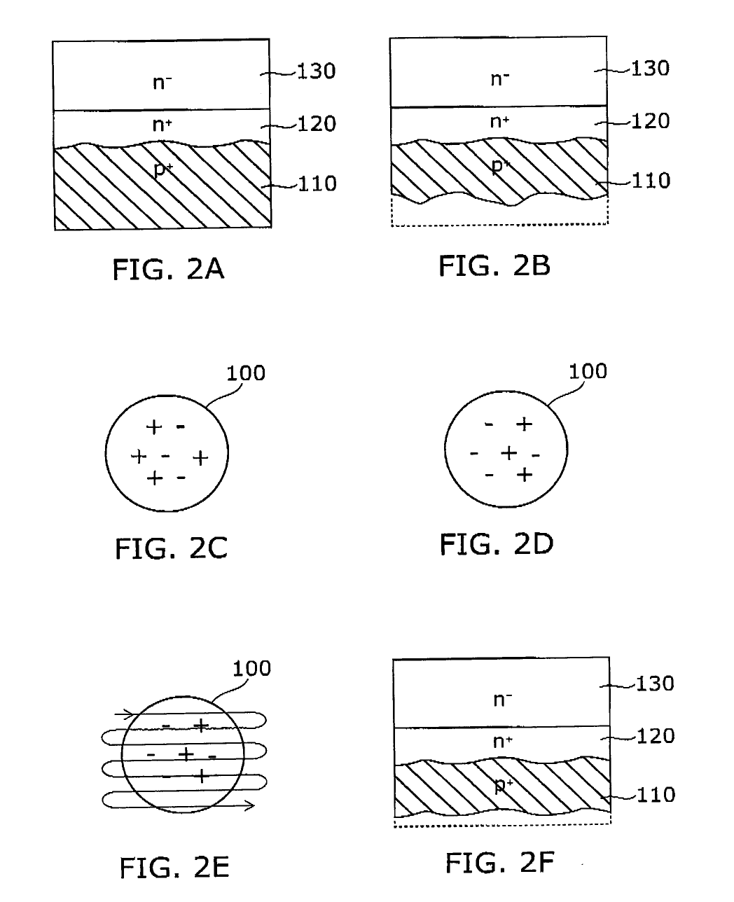

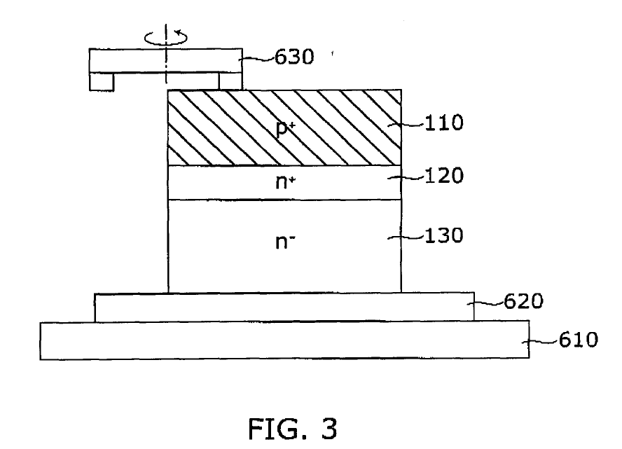

FIGS. 2A to 2F are conceptual views illustrating the manufacturing method of this embodiment. More specifically, FIGS. 2A, 2B, and 2F are partial cross-sectional views of a wafer, and FIGS. 2C, 2D, and 2E are plan views of the waver.

In this embodiment, a primary process is first performed (step S102). This illustratively includes, in the example shown in FIGS. 2A to 2F, a process of epitaxially growing an n⁺-type silicon layer 120 and an n⁻-type silicon layer 130 in this order on a p⁺-type silicon substrate 110 as shown in FIG. 2A, and a process of polishing/grinding the backside of the p⁺-type silicon substrate 110 as shown in FIG. 2B.

These various processes may involve within-wafer variations.

For example, the p⁺-type silicon substrate 110 serving as a starting material may initially include variations in thickness and dopant concentration. In FIGS. 2A to 2F, these variations are conceptually represented as surface irregularities of the p⁺-type silicon substrate 110. Like this, there may be cases where the thickness and dopant concentration of a semiconductor substrate is not substantially uniform, but varied, within the wafer. Furthermore, as shown in FIG. 2A, for example, also in forming a semiconductor layer by epitaxial growth or dopant diffusion, various within-wafer factors such as the temperature distribution, the distribution of the amount supplied and composition of raw material gas, and the pressure distribution of the atmosphere may cause variations in the thickness of semiconductor layers, p-type and n-type dopant concentration, or compositions

Moreover, as shown in FIG. 2B, within-wafer variations may occur also in etching and grinding a wafer.

FIG. 3 is a conceptual view for Illustrating a process of grinding a wafer.

More specifically, in grinding a wafer, the wafer is stuck on a tape 620 and mounted on a stage 610 serving as a reference plane. The wafer surface is successively ground by a rotated grindstone 630, and further polished. Here, for example, the thickness of the tape 620 and the gap formed between the wafer and the tape 620 may have uneven distribution. Furthermore, the amount of contact of the grindstone 630 may have uneven distribution. These factors may cause within-wafer thickness variations after grinding. Similar variations may occur also in the case of wet etching and dry etching.

In the example shown in FIG. 2B, the thickness variations caused in the process of grinding the p⁺-type silicon substrate 110 are conceptually represented as irregularities on the backside.

If a wafer having such variations in thickness or dopant concentration is directly used to form semiconductor devices, the characteristics of the semiconductor devices obtained from this wafer will not be uniform, but will be varied. As described later in detail, in manufacturing an IGBT (insulated gate bipolar transistor) or a diode, for example, the thickness and dopant concentration of the p⁺-type silicon substrate 110 are the factors determining the threshold and operating voltage of the device. Hence, to equalize device characteristics, the thickness and dopant concentration of the p⁺-type silicon substrate 110 need to be equalized within a wafer.

In this respect, in this embodiment, the wafer after the completion of the primary process is measured for the within-wafer distribution of physical quantities (step S104). The physical quantities measured here relate to the thickness, dopant concentration, and the amount of dopant, for example. However, the measurement is not limited to direct measurement of thickness and dopant concentration, but physical quantities related thereto may be measured. In the example shown in FIGS. 2A to 2F, for example, the sheet resistance of the p⁺-type silicon substrate 110 can be measured. More specifically, the sheet resistance of the p⁺-type silicon substrate 110 can be measured by the four-probe method or the like from the backside of the wafer. Here, the size of the probe used in the four-probe method or the like is e.g. substantially several millimeters, and the within-wafer distribution of sheet resistance of the p⁺-type silicon substrate 110 can be measured throughout the wafer backside by successively shifting the probes at a prescribed pitch. As the pitch for shifting the probes becomes smaller, a finer within-wafer distribution can be obtained. In FIG. 2C, the distribution of the measured physical quantity is conceptually represented by + (plus) and − (minus) symbols.

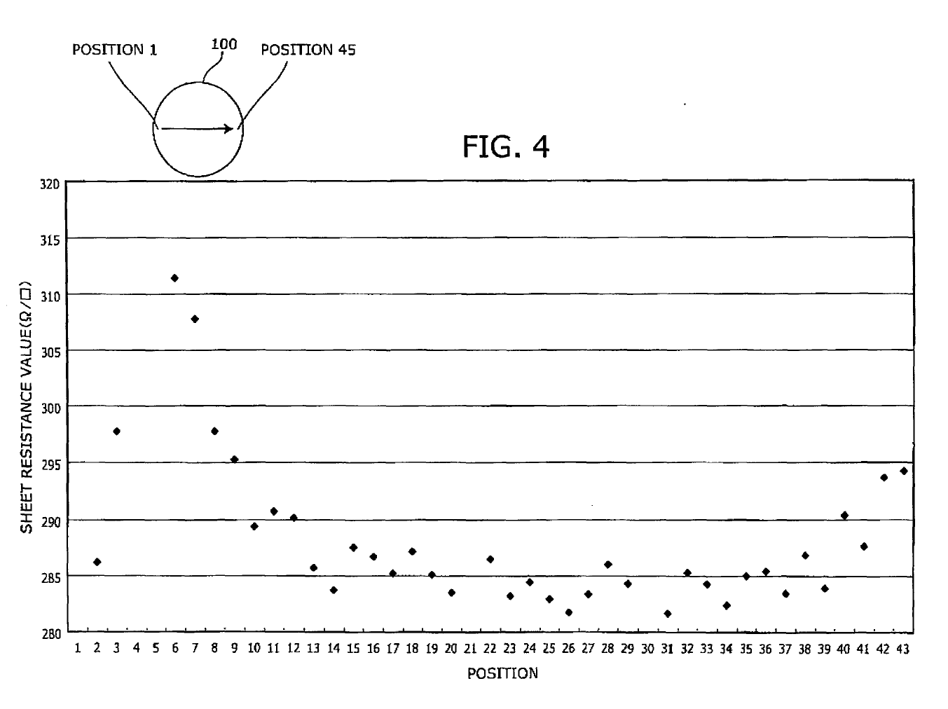

FIG. 4 is a graph showing the experimental result of measuring the sheet resistance distribution of a silicon wafer after grinding.

Here, a 6-inch silicon wafer having an initial thickness of 625 micrometers was ground to a target thickness of 155 micrometers. Then the sheet resistance distribution of the wafer was measured. The horizontal axis of FIG. 4 represents the within-wafer position, and both end of the axis generally correspond to both end of the wafer as shown in the inset. The vertical axis of FIG. 4 represents the sheet resistance value (Ω/□).

As seen from FIG. 4, the sheet resistance value has a large peak on the observer's left of the wafer, and increases also at the right end. Furthermore, it turns out that, even in the flat portion between these ends, the sheet resistance value fluctuates slightly periodically.

As described later in detail, sheet resistance is a physical quantity reflecting thickness and dopant concentration. The distribution of thickness and dopant concentration of the p⁺-type silicon substrate 110 can be known by measuring the sheet resistance distribution.

The physical quantity measured in this embodiment is not limited to sheet resistance. For example, the thickness and dopant concentration may be each measured by separate methods. Specifically, the thickness distribution may be measured by an optical method, and the dopant concentration distribution may be measured by the C-V (capacitance-voltage) method using a mercury probe. Furthermore, the physical quantity measured is not limited to its absolute value, but its relative distribution within a wafer may be measured.

Moreover, while the physical quantity of the p⁺-type silicon substrate 110 is measured in this example, other silicon layers may be measured, or the total thickness and electrical characteristics thereof may be measured.

After the within-wafer distribution of the physical quantity is measured in this manner, the etching amount is next calculated (step S106). More specifically, the within-wafer distribution of the measured physical quantity is used to calculate the etching amount required for substantially equalizing it to a prescribed value of the physical quantity. For example, to equalize the thickness of the p⁺-type silicon substrate 110, as viewed within the wafer, the etching amount is increased in a thick portion of the p⁺-type silicon substrate 110 and decreased in a thin portion thereof.

On the other hand, to substantially equalize the sheet concentration of carriers in the p⁺-type silicon substrate 110, on the basis of the distribution of thickness and dopant concentration measured in step S104, the etching amount is increased at positions with high sheet carrier concentration in the p⁺-type silicon substrate 110, and decreased at positions with low sheet carrier concentration. In FIG. 2D, the distribution of the calculated etching amount is conceptually represented by + (plus) and − (minus) symbols. Here, the notion of substantially equalizing sheet dopant concentration applies if it is nearly uniform in a region of substantially 1/10 to ⅕ of the area of one semiconductor chip such as IGBT. This also applies to examples described below.

After calculating the within-wafer distribution of etching amount in this manner, local etching is performed (step S108). More specifically, in contrast to uniformly etching the entire surface of a wafer, the distribution of etching amount calculated in step S106 is used to locally etch individual portions of the wafer as shown in FIG. 2E.

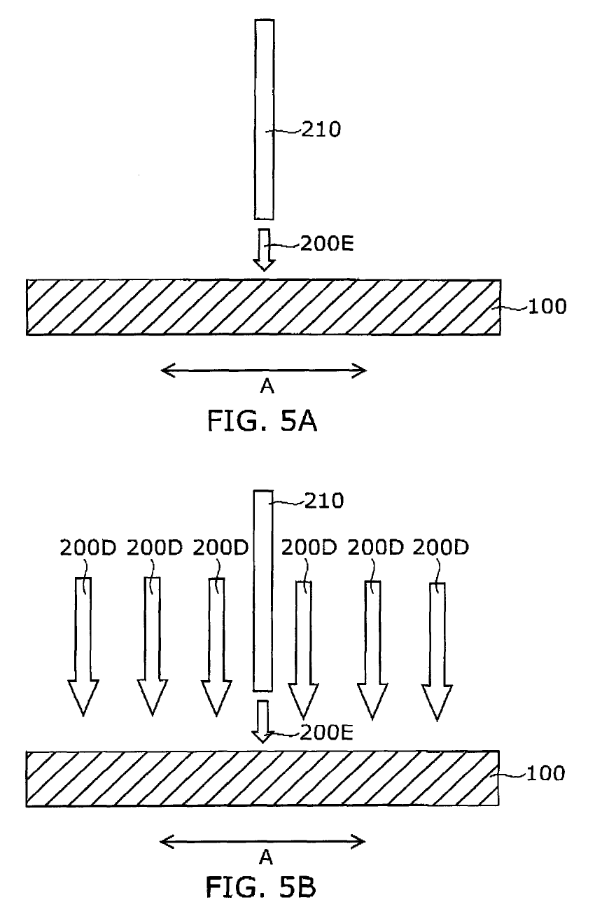

FIGS. 5A and 5B are conceptual views of local etching.

More specifically, an etchant 200E is locally supplied through a nozzle 210, for example, to the surface of a wafer 100 to be etched. Then, as shown by arrow A, the wafer 100 and the nozzle 210 are relatively displaced. Here, at a position where the etching amount is to be increased, the etching amount can be increased by extending etching time or increasing the concentration or amount supplied of the etchant. At a position where the etching amount is to be decreased, the nozzle 210 can be rapidly passed, or supply of etchant can be stopped.

Here, the etching method may be whether wet etching or dry etching. In the case of wet etching, a chemical liquid is dropped or squirted from the nozzle 210 to the surface of the wafer 100. Here, to prevent the portion other than the position directly below the nozzle 210 from being etched, for example, as shown in FIG. 5B, water or other diluting medium 200D can be sprayed or squirted around the nozzle 210.

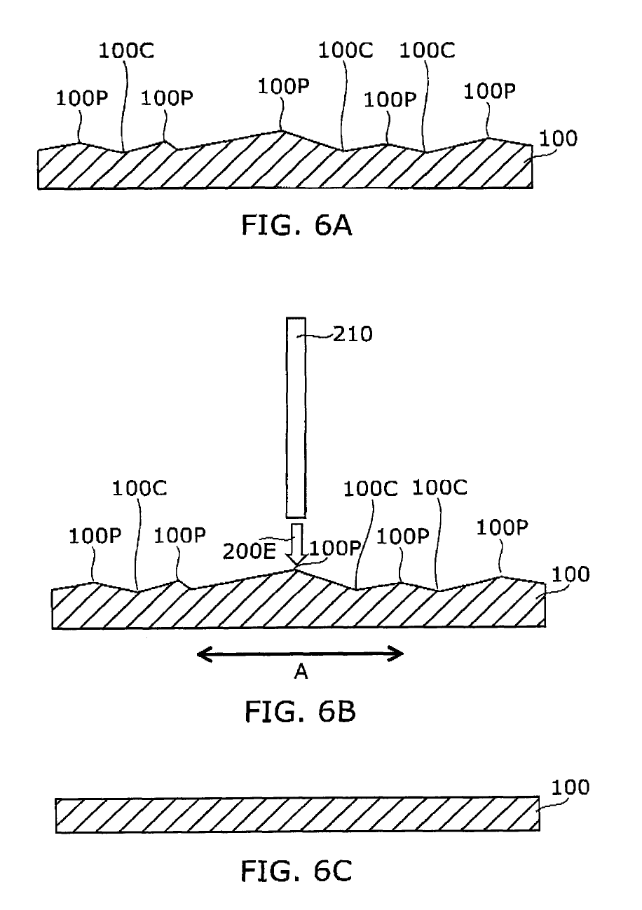

FIGS. 6A, 6B and 6C are a conceptual views showing the function of local etching.

For example, in the case where the surface of a wafer 100 has irregularities as shown in FIG. 6A, an etchant 200E is locally supplied from the nozzle 210 as shown in FIG. 6B, and the wafer 100 and the nozzle 210 are relatively displaced as shown by arrow A. Here, at a protrusion 100P, the transit time of the nozzle 210 is increased, and the etching time is increased. On the other hand, at a recess 100C, the transit time of the nozzle 210 is decreased, and the etching time is decreased. This accelerates etching of the protrusion 100P, and consequently, a flat wafer 100 is obtained as shown in FIG. 6C.

The inner diameter of the nozzle 210 for supplying an etchant can be substantially several hundred micrometers to 10 millimeters, for example. As the inner diameter of the nozzle 210 becomes smaller, a finer region can be selectively etched. On the other hand, if the nozzle 210 has a large inner diameter, the etching rate can be easily increased. Decreasing the speed or pitch of relative displacement of the wafer 100 and the nozzle 210 facilitates selectively etching a finer region.

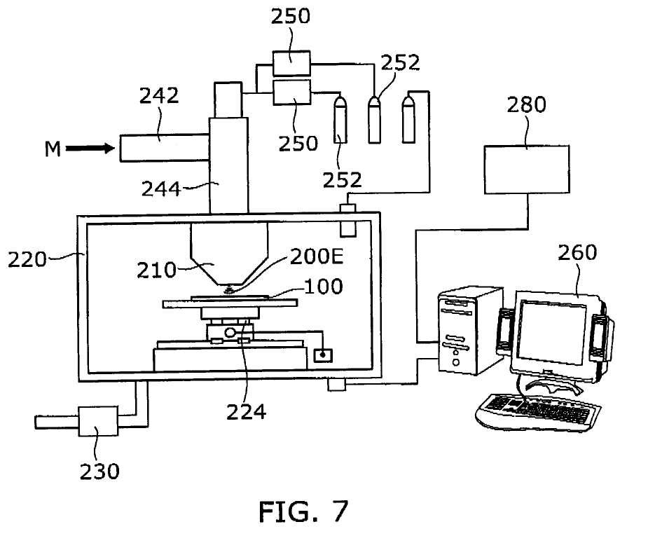

FIG. 7 is a conceptual view showing local etching by dry etching.

More specifically, an X-Y movable stage 224 is provided in a vacuum chamber 220, and a wafer 100 is mounted on the stage 224. The vacuum chamber 220 is evacuated by a vacuum pump 230 and can maintain a reduced-pressure atmosphere. A nozzle 210 is placed opposite to the wafer 100. The nozzle 210 is in communication with an electric discharge tube 244 provided outside the chamber 220. The discharge tube 244 is supplied with an etching or diluting gas 250 through a gas supply controller 252. The discharge tube 244 is further supplied with a microwave M through a waveguide 242, and thereby a plasma of the gas 250 is generated.

For example, in the case where the gas 250 is a fluorine-based gas such as SF₆, generation of its plasma results in generating an active species such as fluorine radicals. The active species 200E is supplied from the nozzle 210 to the surface of the wafer 100. The fluorine active species 200E supplied to the surface of the wafer 100 locally etches silicon. Hence, on the basis of the distribution of etching amount calculated in step S106, a prescribed physical quantity such as within-wafer thickness or dopant concentration can be substantially equalized by increasing the etching time in a portion of large etching amount and decreasing the etching time in a portion of small etching amount during moving the stage 224.

As described above, by local etching, the within-wafer distribution of a physical quantity can be substantially equalized to a prescribed value of the physical quantity. In the example shown in FIG. 2F, for instance, on the basis of the sheet resistance distribution of the p⁺-type silicon substrate 110, the p⁺-type silicon substrate 110 can be locally etched so that the distribution is substantially equalized to a prescribed sheet resistance. Consequently, the variations of sheet resistance value of the p⁺-type silicon substrate 110 can be eliminated.

Subsequently, a secondary process is performed (step S110). The secondary process is needed to complete semiconductor devices after local etching, and suitably includes formation of additional semiconductor layers, formation of electrodes, and formation of protective film, for example. However, the secondary process is not essential to the invention, but the semiconductor devices may be completed with local etching.

As described above, according to this embodiment, the within-wafer characteristics variations can be restrained by measuring the within-wafer distribution of a physical quantity and locally etching the wafer on the basis thereof. Consequently, the characteristics of a plurality of semiconductor devices obtained from at least one wafer can be equalized.

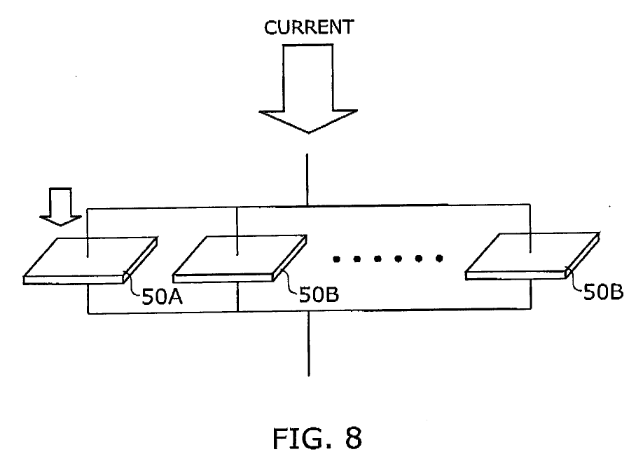

FIG. 8 is a conceptual view of a circuit where a plurality of semiconductor devices are connected in parallel.

For example, in the case where IGBT or other semiconductor devices 50A, . . . , 50B are connected in parallel, if one of the semiconductor devices 50A, . . . , 50B has a particularly low resistance during energization (ON resistance), the current concentrates on this semiconductor device (50A), which may result in overheat, decreased lifetime, or breakdown.

In contrast, according to this embodiment, within-wafer characteristics variations are prevented, and semiconductor devices with uniform characteristics can be stably manufactured. Furthermore, when the physical quantity measured in step S104 is controlled by its absolute value, the characteristics of semiconductor devices can be equalized not only in one wafer but also among a plurality of wafers.

### EXAMPLES

In the following, the embodiment of the invention is described in more detail with reference to examples.

### First Example

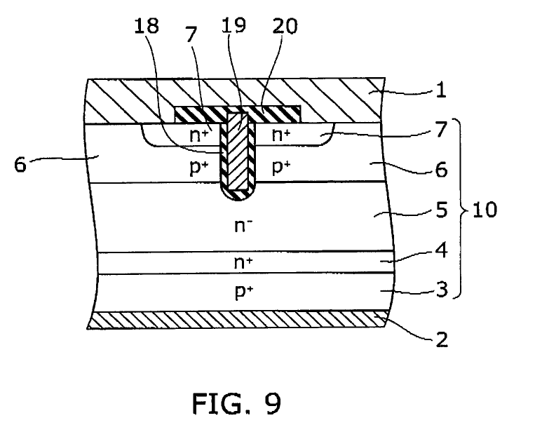

FIG. 9 is a schematic view showing the cross-sectional structure of a semiconductor device manufactured by the manufacturing method according to the embodiment of the invention.

The semiconductor device shown in FIG. 9 is an IGBT of the trench gate structure. This IGBT includes an n⁺-type buffer layer 4 and an n⁻-type base layer 5 sequentially on a p⁺-type silicon substrate (collector layer) 3. In this structure, a p⁺-type base region 6 is provided in the surface portion of the n⁻-type base layer 5, and an n⁺-type emitter region 7 is selectively provided in the surface of the base region 6.

From the surface of the emitter region 7 corresponding to the first major surface of the semiconductor layer 10, a trench is formed through the emitter region 7 and the base region 6 to the n⁻-type base layer 5. The trench is filled in with a control electrode 19 via an insulating film 18. In the base region 6, the portion opposed to the control electrode 19 across the insulating film 18 functions as a channel formation region.

A first main electrode 1 is provided on the surface of the emitter region 7 and the base region 6 (the surface corresponding to the first major surface of the semiconductor layer 10). An interlayer insulating film 20 is interposed between the first main electrode 1 and the control electrode 19.

A second main electrode 2 is provided on the backside of the collector layer 3, which corresponds to the second major surface of the semiconductor layer 10.

In the IGBT described above, upon application of a desired control voltage (gate voltage) to the control electrode 19, an n-channel is formed in the channel formation region opposed to the control electrode 19 across the insulating film 18, and the path between the first main electrode 1 and the second main electrode 2 (emitter-collector path) is turned into the ON state. In an IGBT, electrons and holes are injected from the emitter and the collector, respectively, and carriers are accumulated in the n⁻-type base layer 5, thereby causing conductivity modulation. Hence the ON resistance can be made lower than in the vertical MOSFET (metal-oxide-semiconductor field effect transistor).

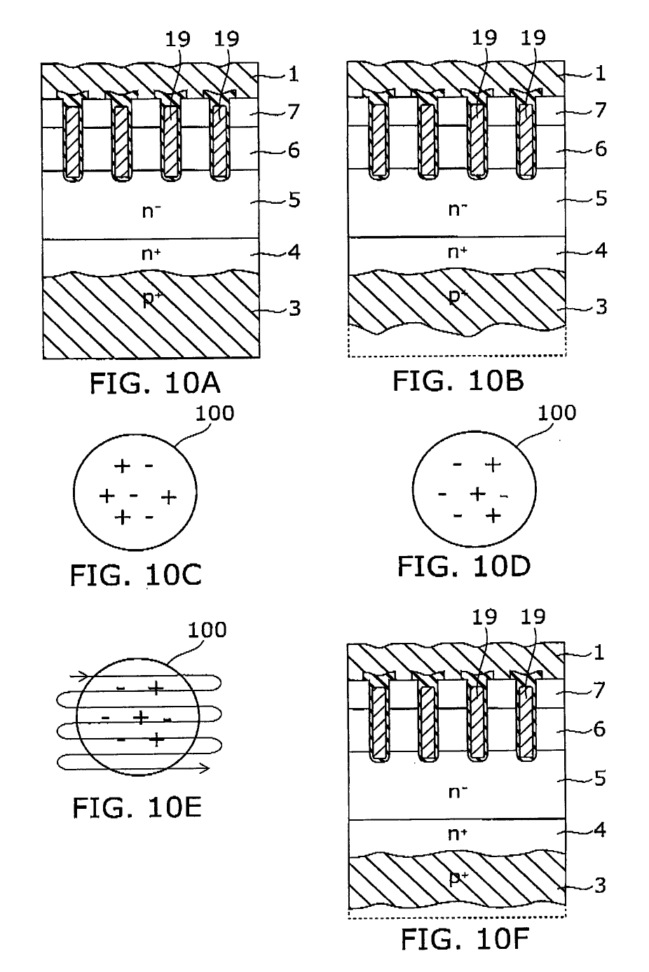

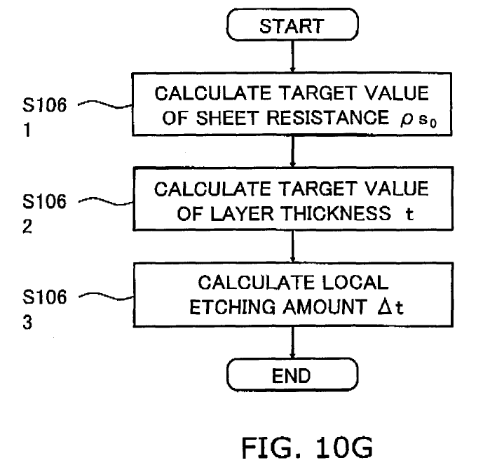

FIGS. 10A to 10F are conceptual views showing a method for manufacturing an IGBT shown in FIG. 9, the method being a first example of the embodiment of the invention. In FIG. 10 and the following figures, part of the structure of the IGBT shown in FIG. 9 is omitted.

First, as the primary process, the process shown in FIGS. 10A and 10B is performed. More specifically, as shown in FIG. 10A, a p⁺-type silicon layer 3 is used as a substrate, on which the structure from the n⁺-type buffer layer 4 to the first main electrode 1 is formed. Furthermore, as shown in FIG. 10B, the p⁺-type silicon layer 3 used as a substrate is ground from its backside. In this process sequence, the wafer incurs variations in thickness and dopant concentration originally possessed by the p⁺-type silicon layer 3 used as a substrate and variations in thickness caused by grinding from the backside.

Subsequently, as shown in FIG. 10C, the distribution of sheet resistance value of the p⁺-type silicon layer 3 is measured. This can be measured, as described above, by the four-probe method or the like from the backside of the p⁺-type silicon layer 3.

Next, as shown in FIG. 10D, the distribution of etching amount for the p⁺-type silicon layer 3 is calculated. Here, in the case of an IGBT, the sheet dopant concentration in the p⁺-type silicon layer 3 affects the ON resistance of the completed IGBT. Hence, the etching amount is preferably determined so that the product of the dopant concentration p in the p⁺-type silicon layer 3 and the thickness t thereof, p×t (=sheet dopant concentration) is equalized within the wafer.

The calculation of etching amount (step S106 shown in FIG. 1) is performed by a method as exemplarily shown in FIG. 10G.

FIG. 10G is a flow chart of a part of a method for manufacturing a semiconductor device according to the embodiment of the invention. As shown in FIG. 10G, the calculation of etching amount includes; calculating target value of sheet resistance ρs₀ (S1061), calculating target value of layer thickness t (S1062), and calculating local etching amount Δt based on the target value of sheet resistance ρs₀ and the layer thickness t (S1063).

The following relation holds between the thickness t of the p⁺-type silicon layer 3 and the sheet resistance ρₛ:

σ=1/ρ=1/(ρₛ×t)=q×μₚ×p (1)

σ: conductivity

ρ: resistivity

q: elementary charge

μₚ: hole mobility

p: dopant concentration in the p⁺-type silicon layer 3

The following relation can be derived from formula (1);

ρₛ=1/(q×μ_{p×p×t})

That is, if the mobility μₚ is constant, the sheet resistance ρₛ is inversely proportional to the sheet dopant concentration p×t. Hence, if local etching is performed so as to equalize the sheet resistance of the p⁺-type silicon layer 3, the sheet dopant concentration p×t can be also equalized.

For example, for a target value Qₒ (cm⁻²) of sheet dopant concentration p×t in the p⁺-type silicon layer 3 after local etching, the target value of sheet resistance, ρₛₒ, can be expressed as:

ρₛₒ=1/(q×μₚ×Qₒ) (2)

On the other hand, from formula (1), the thickness t can be expressed as:

t=1/(q×μₚ×p×pₛ)

A correction coefficient A is introduced for taking into consideration the measurement error of sheet resistance ρₛ. Then the etching amount Δt for the p⁺-type silicon layer 3 can be expressed as:

Δt=(1/Aρₛ−1/ρₛₒ)/(q×μₚ×p×ρₛ) (3)

If the target value Qₒ (cm⁻²) of sheet dopant concentration p×t in the p⁺-type silicon layer 3 is determined, the etching amount for the p⁺-type silicon layer 3 can be calculated from the sheet resistance ρₛ on the basis of formulas (2) and (3). Here, the correction coefficient A can be suitably determined by characterizing the IGBT through preliminary experiments.

As described above, in this example, the p⁺-type silicon layer 3 is locally etched (FIG. 10E) so that the sheet resistance of the p⁺-type silicon layer 3 is equalized within the wafer. Thus its sheet dopant concentration p×t can be substantially equalized. Consequently, variations in ON resistance of the IGBT can be prevented, and IGBTs with uniform characteristics can be stably manufactured.

As shown in FIG. 10F, after the sheet dopant concentration p×t in the p⁺-type silicon layer 3 is substantially equalized to a prescribed value, a second main electrode 2 is formed on its backside, and thus an IGBT shown in FIG. 9 is completed.

For example, if the total thickness of the wafer is measured and the measurement value is used to control the thickness of the p⁺-type silicon layer 3, the control is inaccurate in that it is also affected by variations in thickness of the n⁺-type buffer layer 4 and the n⁻-type base layer 5. In contrast, according to this example, by measuring the sheet resistance of the p⁺-type silicon layer 3 using the four-probe method or the like instead of simply measuring the thickness, its sheet dopant concentration p×t can be reliably and easily measured.

### SECOND EXAMPLE

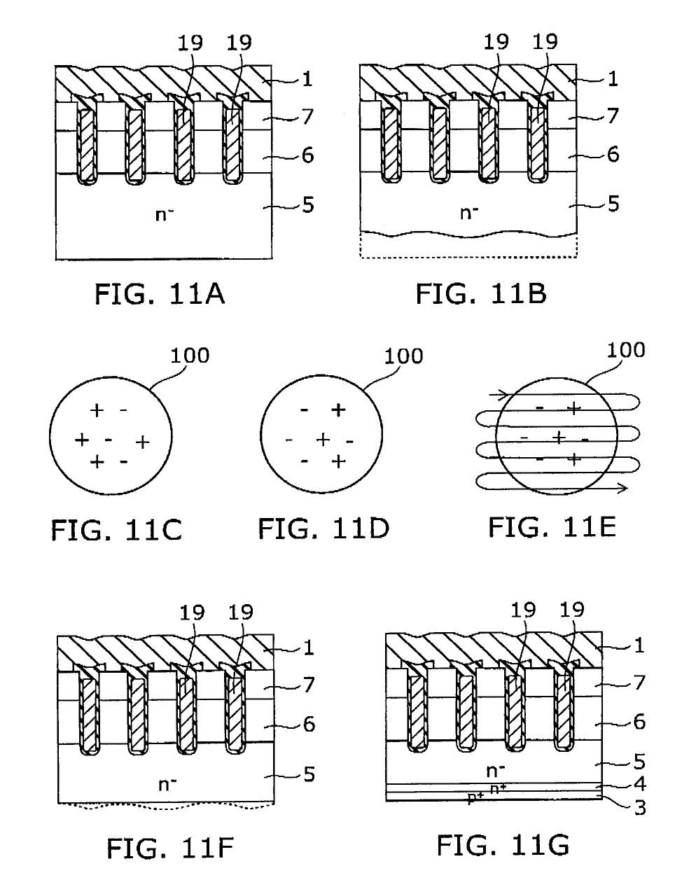

FIGS. 11A to 11G are conceptual views showing a method for manufacturing an IGBT shown in FIG. 9, the method being a second example of the embodiment of the invention,

In this example, an n⁻-type base layer 5 is used as a substrate. More specifically, as shown in FIG. 11A, the structure from the base layer 6 to the first main electrode 1 is formed on the n⁻-type base layer 5. Then, as shown in FIG. 11B, the n⁻-type base layer 5 used as a substrate is ground from its backside. Here, the wafer incurs variations in thickness of the n⁻-type base layer 5 caused by grinding from the backside. The variations in thickness of the n⁻-type base layer 5 also causes variations in ON resistance of the IGBT.

Hence, next, as shown in FIG. 11C, the thickness distribution of the silicon layer of the wafer is measured. As an example method for this measurement, infrared radiation is applied from the backside of the wafer, and the total thickness of the silicon layer can be measured on the basis of light reflected by the backside and frontside of the silicon layer included in the wafer. Alternatively, the FT-IR (fast Fourier transform infrared spectroscopy) method or a film thickness gage of the contact stylus type can be also used.

After the thickness distribution of the silicon layer is thus measured, as shown in FIG. 11D, the distribution of etching amount for the n⁻-type base layer 5 is calculated. More specifically, the etching amount is calculated so that the n⁻-type base layer 5 attains the target thickness throughout the wafer.

Subsequently, as shown in FIG. 11E, local etching is performed. Thus, as shown in FIG. 11F, the thickness of the n⁻-type base layer 5 can be substantially equalized to the target value (prescribed value) throughout the wafer.

Then, as shown in FIG. 11G, n-type dopant and p-type dopant are implanted from the backside of the n⁻-type base layer 5 and annealed to form an n⁺-type buffer layer 4 and a p⁺-type silicon layer 3, respectively.

As described above, in this example, variations in thickness of the n⁻-type base layer 5 can be eliminated so that it attains the target value throughout the wafer. Consequently, IGBTs with uniform characteristics can be stably manufactured.

### Third Example

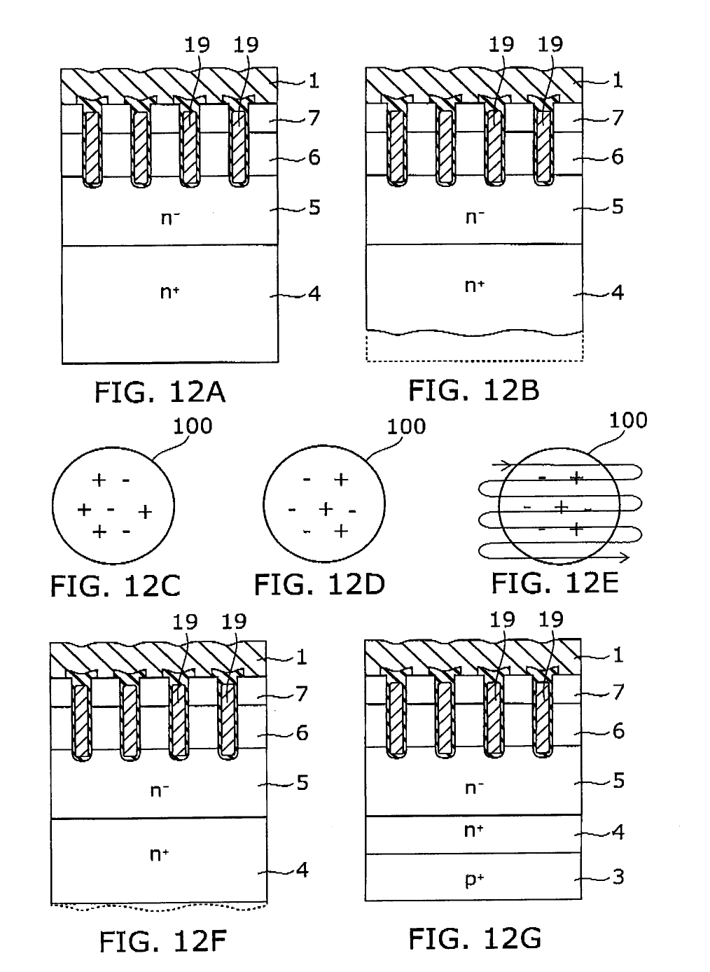

FIGS. 12A to 12G are conceptual views showing a method for manufacturing an IGBT shown in FIG. 9, the method being a third example of the embodiment of the Invention.

In this example, an n⁺-type buffer layer 4 is used as a substrate. More specifically, as shown in FIG. 12A, the structure from the n⁻-type base layer 5 to the first main electrode 1 is formed on the n⁺-type buffer layer 4. Then, as shown in FIG. 12B, the n⁺-type buffer layer 4 used as a substrate is ground from its backside. Here, the wafer incurs variations in thickness of the n⁺-type buffer layer 4 caused by grinding from the backside. The variations in thickness of the n⁺-type buffer layer 4 also causes variations in ON resistance and threshold voltage.

Hence, next, as shown in FIG. 12C, the within-wafer distribution of sheet resistance of the n⁺-type buffer layer 4 is measured. As an example method for this measurement, the four-probe method or the like can be used as described above. Here, the n⁻-type base layer 5 underlying the n⁺-type buffer layer 4 typically has a lower dopant concentration than the buffer layer 4, and hence the error in measuring sheet resistance is small.

After the sheet resistance distribution of the n⁺-type buffer layer 4 is thus measured, as shown in FIG. 12D, the distribution of etching amount for the n⁺-type buffer layer 4 is calculated. More specifically, the etching amount is calculated so that the sheet resistance of the n⁺-type buffer layer 4 attains the target value (prescribed value) throughout the wafer.

Subsequently, as shown in FIG. 12E, local etching is performed. Thus, as shown in FIG. 12F, the sheet resistance of the n⁺-type buffer layer 4 can be substantially equalized to the target value throughout the wafer. As in the first example, the sheet dopant concentration p×t can be substantially equalized by controlling the sheet resistance of the n⁺-type buffer layer 4, and variations in ON resistance and threshold voltage can be prevented.

Then, as shown in FIG. 12G, p-type dopant is implanted from the backside of the n⁺-type buffer layer 4 and annealed to form a p⁺-type silicon layer 3.

As described above, in this example, variations in sheet resistance of the n⁺-type buffer layer 4 can be eliminated so that it attains the target value throughout the wafer. Consequently, IGBTs with uniform characteristics can be stably manufactured.

### Fourth Example

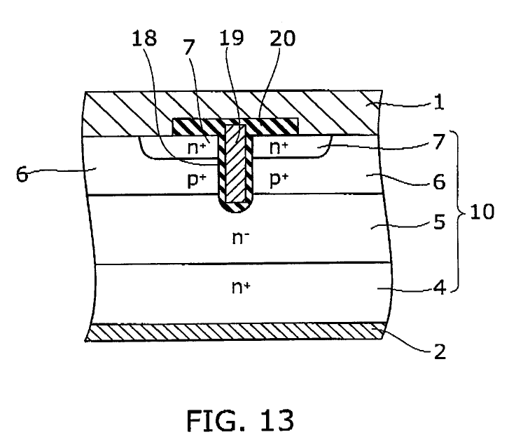

FIG. 13 is a schematic view showing the cross-sectional structure of a semiconductor device manufactured by the manufacturing method according to the embodiment of the invention.

The semiconductor device of this example is a MOSFET (metal-oxide-semiconductor field effect transistor) of the trench gate type. This MOSFET has a structure similar to that of the IGBT described above with reference to FIG. 9. Hence similar elements are marked with like reference numerals and are not described in detail. A major difference from the IGBT shown in FIG. 9 is lack of the p⁺-type silicon layer 3.

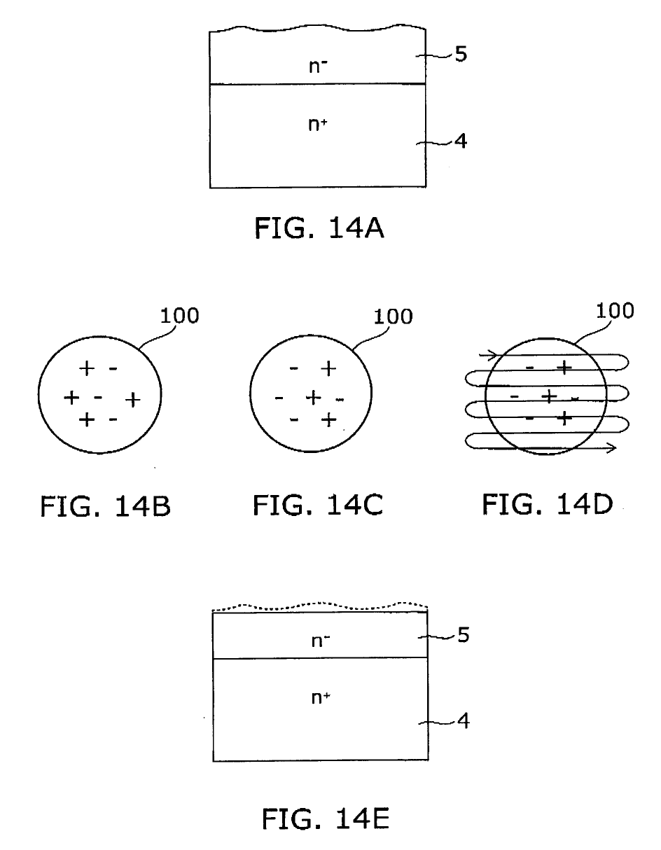

FIGS. 14A to 14E are conceptual views showing part of a method for manufacturing a MOSFET shown in FIG. 13, the method being a fourth example of the embodiment of the invention.

In this example, an n⁺-type buffer layer 4 is used as a substrate. More specifically, as shown in FIG. 14A, an n⁻-type base layer 5 is epitaxially grown on the n⁺-type buffer layer 4. Here, variations in thickness of the n⁻-type base layer 5 cause variations in ON resistance of the MOSFET. In the case of using a typical epitaxial growth such as the vapor-phase growth, variations in thickness of the n⁻-type base layer 5 across a 6-inch wafer may exceed ±5 percent. Hence, in this example, as shown in FIG. 14B, the thickness distribution of the n⁻-type base layer 5 is measured. As an example method for this measurement, as described above, an optical method such as the FT-IR (fast Fourier transform infrared spectroscopy) method or a film thickness gage of the contact stylus type can be used.

After the thickness distribution of the n⁻-type base layer 5 is thus measured, as shown in FIG. 14C, the distribution of etching amount for the n⁻-type base layer 5 is calculated. More specifically, the etching amount is calculated so that the n⁻-type base layer 5 attains the target thickness throughout the wafer.

Subsequently, as shown in FIG. 14D, local etching is performed. Thus, as shown in FIG. 14E, the thickness of the n⁻-type base layer 5 can be substantially equalized to the target value throughout the wafer. Variations in ON resistance can be prevented by controlling the thickness of the n⁻-type base layer 5.

Then, the structure from the p⁺-type base region 6 to the first main electrode 1 is formed on the n⁻-type base layer 5, and a second main electrode 2 is formed on the backside of the n⁺-type buffer layer 4. Thus a MOSFET shown in FIG. 13 is completed.

As described above, in this example, variations in thickness of the n⁻-type base layer 5 can be eliminated so that it is substantially equalized to a target value throughout the wafer. Consequently, MOSFETs with uniform characteristics can be stably manufactured.

The embodiment of the invention has been described with reference to examples. However, the invention is not limited to these examples.

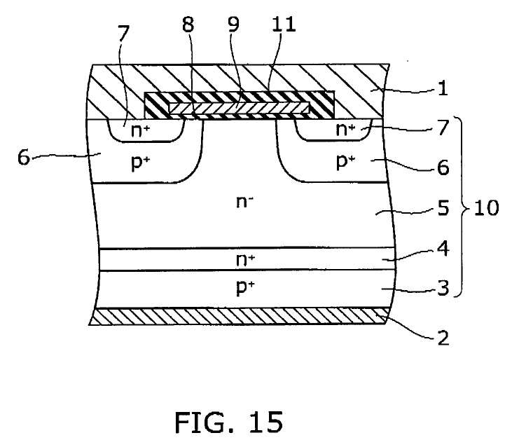

FIG. 15 is a cross-sectional view showing a semiconductor device that can be manufactured by the embodiment of the invention.

The semiconductor device of this example is an IGBT of the planar gate structure. This IGBT includes an n⁺-type buffer layer 4 and an n⁻-type base layer 5 sequentially on a p⁺-type silicon layer (collector layer) 3. In this structure, a p⁺-type base region 6 is selectively provided in the surface portion of the n⁻-type base layer 5, and an n⁺-type emitter region 7 is selectively provided in the surface of the base region 6.

A control electrode 9 is provided via an insulating film 8 on the surface extending from a portion of the emitter region 7 through the base region 6 to the n⁻-type base layer 5 (the surface corresponding to the first major surface of the semiconductor layer 10). The surface portion of the base region 6 opposed to the control electrode 9 across the insulating film 8 functions as a channel formation region.

The control electrode 9 is covered with an interlayer insulating film 11, and a first main electrode 1 is provided in contact with the emitter region 7 so as to cover the interlayer insulating film 11.

A second main electrode 2 is provided on the backside of the collector layer 3, which corresponds to the second major surface of the semiconductor layer 10.

Also to such an IGBT of the planar gate structure, a manufacturing method similar to that described above with reference to the first to third example, for instance, can be applied, and similar advantageous effects can be achieved.

Furthermore, in each of the above examples, the invention is also applicable to structures with semiconductors having reversed conductivity types, and various other IGBTs, MOSFETs, and diodes, achieving similar advantageous effects.

Besides silicon, various semiconductor materials such as GaAs, SiC, GaN, Ge, and SiGe can be used.

1. A method for manufacturing a semiconductor device, comprising:
measuring a within-wafer distribution of a physical quantity of at least one of a plurality of semiconductor layers provided in a wafer;
determining a within-wafer distribution of etching amount for the at least one of the plurality of semiconductor layers based on the measured within-wafer distribution of the physical quantity; and
etching the at least one of the plurality of semiconductor layers based on the determined within-wafer distribution of the etching amount so that the etching amount is locally varied within the wafer.

2. The method for manufacturing a semiconductor device according to claim 1, wherein the physical quantity is a physical quantity reflecting dopant concentration in the at least one of the plurality of semiconductor layers.

3. The method for manufacturing a semiconductor device according to claim 2, wherein the within-wafer distribution of the etching amount is determined so that sheet concentration of dopant contained in the at least one of the plurality of semiconductor layers get close to constant within the wafer.

4. The method for manufacturing a semiconductor device according to claim 1, wherein the physical quantity is sheet resistance of the at least one of the plurality of semiconductor layers.

5. The method for manufacturing a semiconductor device according to claim 4, wherein the within-wafer distribution of the etching amount is determined so that the sheet resistance is substantially constant within the wafer.

6. The method for manufacturing a semiconductor device according to claim 1, wherein the physical quantity is a physical quantity reflecting thickness of the at least one of the plurality of semiconductor layers.

7. The method for manufacturing a semiconductor device according to claim 6, wherein the within-wafer distribution of the etching amount is determined so that thickness of the at least one of the plurality of semiconductor layers get close to constant within the wafer.

8. The method for manufacturing a semiconductor device according to claim 1, further comprising grinding the wafer before the measuring the within-wafer distribution

9. The method for manufacturing a semiconductor device according to claim 1, further comprising epitaxially growing the at least one of the plurality of semiconductor layers.

10. The method for manufacturing a semiconductor device according to claim 1, wherein the etching the at least one of the plurality of semiconductor layers includes supplying an etchant locally on a surface of the wafer.

11. The method for manufacturing a semiconductor device according to claim 10, wherein diluting medium is supplied around the etchant on the surface of the wafer.

12. The method for manufacturing a semiconductor device according to claim 10, wherein the etching the at least one of the plurality of semiconductor layers is performed by a dry etching.

13. A method for manufacturing a semiconductor device, comprising:
measuring a within-wafer distribution of a physical quantity; and
etching the wafer so that the physical quantity get close to constant within the wafer.

14. The method for manufacturing a semiconductor device according to claim 13, wherein the physical quantity is a physical quantity reflecting dopant concentration in a semiconductor layer included in the wafer.

15. The method for manufacturing a semiconductor device according to claim 13, wherein the physical quantity is sheet resistance of a semiconductor layer included in the wafer.

16. The method for manufacturing a semiconductor device according to claim 13, wherein the physical quantity is a physical quantity reflecting thickness of the wafer.

17. The method for manufacturing a semiconductor device according to claim 13, further comprising grinding the wafer before the measuring the within-wafer distribution

18. The method for manufacturing a semiconductor device according to claim 13, further comprising epitaxially growing the at least one of the plurality of semiconductor layers.

19. The method for manufacturing a semiconductor device according to claim 13, wherein the etching the at least one of the plurality of semiconductor layers includes supplying an etchant locally on a surface of the wafer.

20. The method for manufacturing a semiconductor device according to claim 19, wherein diluting medium is supplied around the etchant on the surface of the wafer.
